(19) United States
(12) Patent Application Publication
(10) Pub. No.: US 2006/0056476 A1
(43) Pub. Date: Mar. 16, 2006

(54) Laser diode with corner reflector having emission window

(75) Inventors: Hiroyuki Hiiro, Kanagawa-ken (JP); Hideki Asano, Kanagawa-ken (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 11/225,159

(22) Filed: Sep. 14, 2005

(30) Foreign Application Priority Data
Sep. 14, 2004 (JP) 266695/2004

(51) Int. Cl. H01S 5/00

(52) U.S. Cl. 372/50.124

(57) ABSTRACT

A laser diode includes: a reflection layer, an active layer, and a corner reflector which has a shape approximately corresponding to a portion of a cone or pyramid, and is arranged above the active layer with vertex up so that the corner reflector and the reflection layer realize a resonator. An emission window is formed at a portion, containing the vertex, of the corner reflector, and has such dimensions that substantially only components of oscillated light in a fundamental transverse mode are emitted as a light beam which can propagate outside the laser diode. Instead of provision of the reflection layer, a reflection face may be formed at an end of semiconductor layers, and a corner reflector having an emission window with dimensions as above may be formed at the other end of the semiconductor layers.

### BACKGROUND OF THE INVENTION

1. Field of the Invention

The present invention mainly relates to a laser diode (semiconductor laser), and in particular to a laser diode having a function of suppressing higher-order transverse modes.

2. Description of the Related Art

Currently, the edge-emitting laser diodes (LDs) are widely used. The edge-emitting LDs are constituted by a substrate, semiconductor layers being formed on the substrate and including an active layer, an optical waveguide region which makes light propagate through at least the active layer, and a pair of resonator mirrors which reflect light propagating through the optical waveguide region.

In addition, the surface-emitting LDs are also widely used. The surface-emitting LDs are constituted by a substrate, a lower reflection layer formed on the substrate and realized by, for example, DBR (distributed Bragg reflector) layers, an active layer formed on the upper side of the lower reflection layer (i.e., on the opposite side to the substrate), and an upper reflection layer being formed on the upper side of the active layer and realizing a resonator in cooperation with the lower reflection layer.

Hereinbelow, typical examples of the conventional laser diodes are explained with reference to FIGS. 7 to 10B. (In the drawings accompanying this specification, equivalent elements may bear the same reference numbers even in drawings illustrating different structures, and explanations on the equivalent elements are not repeated in this specification unless necessary.)

FIG. 7 is a schematic side view, partly in cross section, of a first example of a conventional surface-emitting LD. In the surface-emitting LD of FIG. 7, lower DBR layers 2 (as a reflection layer), an active layer 3, an oxidized aperture layer 4, upper DBR layers 5 (as a reflection layer), and a P electrode 6 are formed on one side of a substrate 1, and an N electrode 7 is formed on the opposite side of the substrate 1. In this structure, light generated in the active layer 3 is repeatedly reflected by the upper DBR layers 5 and the lower DBR layers 2 and amplified in the active layer 3 so as to oscillate. Then, a light beam 8 produced by the oscillation is emitted upward through the upper DBR layers 5. Since the extent of the carrier injection opening is limited by the oxidized aperture layer 4, only a portion of the active layer 3 corresponding to the opening of the oxidized aperture layer 4 is excited. That is, the opening of the oxidized aperture layer 4 corresponds to the opening of the oscillation region, i.e., the emission mode area.

The surface-emitting LDs of the above type have the following advantages over the edge-emitting LDs.

(1) The resonator length can be reduced.

(2) High-speed modulation at rates on the order of several GHz or higher is possible.

(3) The driving current can be reduced

(4) Arrayed arrangement can be easily realized.

(5) The cost of mounting can be reduced.

In particular, since high-speed modulation characteristics are required in the field of optical communications, the surface-emitting LDs are widely used as preferable light sources in the field of optical communications.

On the other hand, since it is difficult to realize high output power in the surface-emitting LDs compared with in the edge-emitting LDs, it has been considered to increase the output power by increasing the size of the emission area. However, when the size of the emission area is increased, oscillation in high-order transverse modes is likely to occur. When oscillation in high-order transverse modes occur, various high-order transverse modes are mixed in the oscillation, the far-field intensity distribution of the oscillation beam is double peaked or doughnut shaped. Hereinafter, oscillation beams having a double-peaked far-field intensity distribution may be referred to as double-peaked beams, and oscillation beams having a doughnut-shaped far-field intensity distribution may be referred to as doughnut-shaped beams.

In the case where the laser-diode light sources (LD light sources) are used in optical transmission using optical fibers as transmission mediums, it is necessary to couple light emitted from each LD light source with an optical fiber. In this case, portions of the light emitted from the LD light source in directions nearer to the direction of the optical axis (i.e., the direction perpendicular to the light-emission end face of an LD in the LD light source) are coupled with the optical fiber with higher coupling efficiencies. In other words, portions of the light emitted from the LD light source in directions farther from the direction of the optical axis are coupled with the optical fiber with lower coupling efficiencies. When high-order transverse modes are mixed in a surface-emitting LD, considerable portions of light emitted from the surface-emitting LD make great angles with the optical axis of the surface-emitting LD. Therefore, the amount of light coupled with an optical fiber in the case where the light is emitted from an surface-emitting LD which oscillates in various modes including high-order transverse modes is smaller than in the case where the light is obtained from a laser diode which emits a single-peaked beam.

In addition, suppression of high-order transverse modes and laser beams having a single-peaked far-field intensity distribution are also required for other purposes. For example, the purpose is to increase the circularity of an optical beam to be focused for use. Further, the laser beams having a single-peaked far-field intensity distribution are also required in the edge-emitting LDs.

Conventionally, various structures have been proposed for suppressing high-order transverse modes in laser diodes. FIG. 8 is a schematic side view, partly in cross section, of a second example of a conventional surface-emitting LD, which is proposed for suppressing high-order transverse modes by K. Goto, “Proposal of Ultrahigh Density Optical Disk System Using a Vertical Cavity Surface Emitting Laser Array,” Japanese Journal of Applied Physics, Vol. 37, pp. 2274-2278, 1998.

In the example of FIG. 8, the above structure is formed in a surface-emitting LD, and corner reflectors 10 having a conical or pyramidal shape are arranged, instead of arranging the upper DBR layers 5 as in the structure of FIG. 7, so that resonators are realized by the lower DBR layers 2 and the corner reflectors 10 which are opposed to the lower DBR layers 2 with the active layer 3 between. That is, light generated in the active layer 3 oscillates when the light propagates between each of the corner reflectors 10 and the lower DBR layers 2 through the active layer 3. When the light is reflected by each of the corner reflectors 10, the light is reflected first by a first mirror face of each of the corner reflectors 10, and then by a second mirror face of the corner reflector. Further, at this time, the structure of FIG. 8 is arranged in such a manner that stationary waves are generated and are concentratedly distributed around the vertex of each of the corner reflectors 10, and near-field light 8′ emerges from a region containing the vertex of each of the corner reflectors 10 and having a diameter of tens of nanometers. Such near-field light is suitable for use in high-density recording.

FIG. 9 is a schematic perspective view of an example of a conventional edge-emitting LD, which is proposed for suppressing high-order transverse modes by M. Hagberg et al., “Single-Ended Output GaAs/AlGaAs Single Quantum Well Laser with a Dry-Etched Corner Reflector,” Applied Physics Letters, Vol. 56, Issue 20 (1990) pp. 1934-1936, 14 May 1990. In the structure of FIG. 9, one of reflection mirrors forming an optical resonator is realized by a corner reflector. Specifically, semiconductor layers 22 including an active layer 21 are formed on a substrate 20, and coating which realizes a reflection mirror is applied to an end face 22a of the semiconductor layers 22 so that light which propagates through a stripe region 23 of the semiconductor layers 22 partially passes through the reflection mirror, and the remainder of the light is reflected by the reflection mirror. In addition, a corner reflector 24 is formed at the opposite end of the semiconductor layers 22 by processing the opposite end so as to have a triangular cross section parallel to the semiconductor layers 22.

In the structure of FIG. 9, light incident on the corner reflector 24 is totally reflected at the two faces forming the corner reflector 24. For example, in the case where the vertex angle of the corner reflector 24 is 90 degrees, the light is reflected toward the reflection mirror at the end face 22a. At this time, the phase of the light wave is inverted. Then, the light incident on the end face 22a is reflected toward the corner reflector 24. Thus, the light repeatedly propagates between the corner reflector 24 and the end face 22a, and is amplified in the active layer 21. That is, the light oscillates. The oscillated light partially passes through the coating (reflection mirror) at the end face 22a, and is emitted as an oscillated beam 28.

In the above structure of FIG. 9, light oscillates in only the modes which are inversion symmetric with respect to the optical axis. Therefore, the high-order oscillation modes are suppressed.

In addition, if the vertex angle of the corner reflector 24 is different from 90 degrees, the resonator becomes unstable. However, since only the light in the modes which are inversion symmetric with respect to the optical axis oscillates, high-order oscillation modes are similarly suppressed.

In the structure of FIG. 8, in order to make only the vicinity of the vertex of each of the corner reflectors 10 an effective output window of the near-field light, it is necessary to minimize leakage, from the corner reflectors 10, of the light which can propagate outside the laser diode. Therefore, it is required to set the inclinations and the refractive indexes of the corner reflectors 10 so that the light incident on the corner reflector 24 are totally reflected by the faces of the corner reflector 24, and precisely shape the vertex of the corner reflector 24 so sharply that the vertex has a diameter of approximately 20 nm. The necessity for high-precision shaping raises the cost of the laser diode.

Further, since complete prevention of leakage, from the corner reflectors 10, of the light which can propagate outside the laser diode is required, it is essentially impossible to output and use the light oscillated in the laser diode. In the case where the oscillated light is needed for use in optical communication or the like, it is possible to output the oscillated light through the reflection mirror arranged opposite to the corner reflectors 10. However, since the light oscillates in high-order transverse modes, it is impossible to output a complete, single-peaked beam from the reflection mirror. Therefore, the efficiency in coupling of light with an optical fiber cannot be substantially improved by using the structure of FIG. 8.

On the other hand, since the light in the structure of FIG. 9 also oscillates in the high-order transverse modes which are inversion symmetric with respect to the optical axis, it is impossible to completely suppress the high-order transverse modes. In addition, since the light incident on the corner reflector 24 is totally reflected, it is impossible to output the light oscillated in the laser diode of FIG. 9 from the resonator through the corner reflector 24. Therefore, the light oscillated in the laser diode of FIG. 9 can be outputted through only the end face opposite to the corner reflector 24.

FIG. 10A is a graph indicating a far-field intensity distribution of light emitted from a normal edge-emitting LD having a normal resonator mirror instead of the corner reflector 24, and FIG. 10B is a graph indicating a far-field intensity distribution of light emitted from the edge-emitting LD of FIG. 9. In the case where no corner reflector is arranged, the emitted light has a double-peaked intensity distribution as indicated in FIG. 10A. On the other hand, in the case where the corner reflector is arranged as illustrated in FIG. 9, the far-field intensity distribution of the emitted light has a main lobe corresponding to a single peak and side lobes corresponding to double peaks as indicated in FIG. 10B.

Since the light in the laser beam of FIG. 9 oscillates in the high-order transverse modes as in the structure of FIG. 7, certain amounts of light diffract into the side lobes. At this time, the number of high-order transverse modes in which light oscillates and the amounts of light which diffract into the side lobes increase with the width, in the direction perpendicular to the optical axis, of the waveguide in the laser diode. Therefore, even in the case where the laser diode of FIG. 9 is used, it is essentially impossible to overcome the problem of the reduction in the amount of light coupled with the optical fiber. Further, even in the case where one of resonator mirrors of a surface-emitting LD is realized by a corner reflector and oscillated light is outputted from the opposite side of the surface-emitting LD as in the structure of FIG. 9, it is essentially impossible to overcome the problem of the reduction in the amount of light coupled with the optical fiber for a similar reason.

### SUMMARY OF THE INVENTION

The present invention has been developed in view of the above circumstances.

An aspect of the present invention provides a laser diode which can output a single-peaked, oscillated beam in which high-order transverse modes are suppressed.

The laser diodes according to the present invention have a structure in which light is oscillated by using a corner reflector, and outputs the oscillated light as a single-peaked beam.

Specifically, according to a first aspect of the present invention, there is provided a surface-emitting laser diode comprising: a substrate; a reflection layer formed on the substrate; an active layer formed above the reflection layer; and a corner reflector which has a shape approximately corresponding to a portion of a cone or pyramid having a vertex, and is arranged above the active layer with the vertex up in such a manner that the corner reflector and the reflection layer realize a resonator. The corner reflector has an emission window formed at a portion containing the vertex, and the emission window has such dimensions that substantially only components of oscillated light in a fundamental transverse mode are emitted as a light beam which can propagate outside the surface-emitting laser diode.

In addition, according to a second aspect of the present invention, there is provided an edge-emitting laser diode comprising: a substrate; semiconductor layers which includes an active layer, and is formed on the substrate; an optical waveguide which allows propagation of light so that the light passes through the active layer; a reflection face which is formed at a first end of the semiconductor layers, and reflects light being able to propagate through the optical waveguide; and a corner reflector which is formed at a second end of the semiconductor layers so as to have a protrusion with an approximately triangular cross section parallel to the semiconductor layers in such a manner that an outermost portion of the protrusion corresponds to a vertex of the approximately triangular cross section, and the corner reflector and the reflection face realize a resonator. The corner reflector has an emission window formed at the outermost portion, and the emission window has such dimensions that substantially only the components of oscillated light in a fundamental transverse mode are emitted as a light beam which can propagate outside the edge-emitting laser diode.

(III) The Advantages of the Present Invention are Explained Below.

(a) The advantages of the surface-emitting LD according to the first aspect of the present invention are explained below. For simplifying the explanations, it is assumed that two portions of at least one side surface of the corner reflector which are symmetric with respect to the axis of the cone or pyramid make an angle of 90 degrees. In this case, for example, the light emitted from the active layer and perpendicularly incident on a first portion of the at least one side surface of the corner reflector is totally reflected by the first portion of the at least one side surface toward a direction perpendicular to the direction along which the light emitted from the active layer is incident on the first portion of the at least one side surface, and is then incident on and totally reflected by a second portion of the at least one side surface of the corner reflector toward a direction perpendicular to the direction along which the light is incident on the second portion of the at least one side surface, where the first and second portions are symmetric with respect to the axis of the cone or pyramid. Then, the light reflected by the second portion of the at least one side surface is returned to the active layer, perpendicularly passes through the active layer, is reflected by the reflection layer (which is realized by, for example, the DBR layers), and perpendicularly enters the active layer. Thereafter, the light repeatedly propagates between the corner reflector and the reflection layer, and is amplified in the active layer every time the light passes through the active layer. Therefore, light is oscillated in the resonator realized by the corner reflector and the reflection layer. Since the corner reflector in the surface-emitting LD according to the present invention has the emission window, the oscillated light is emitted from the surface-emitting LD through the emission window as a propagating light beam (i.e., a light beam which can propagate outside the surface-emitting LD).

In addition, since the emission window has such dimensions that substantially only the components of the oscillated light in the fundamental transverse mode are emitted as a light beam which can propagate outside the edge-emitting laser diode, the propagating light beam is a single-peaked light beam which contains substantially only in-phase components, and in which high-order transverse modes are suppressed. In the case where two portions of at least one side surface of the corner reflector which are symmetric with respect to the axis of the cone or pyramid make an angle of 90 degrees, strong optical coupling occurs between two points in the two portions which are symmetric with respect to the axis of the cone or pyramid, and in-phase oscillation occurs in the optical path through the two portions. Since the resonator has a structure which is rotationally symmetric with respect to the axis of the corner reflector, oscillation occurs in only the Laguerre-Gauss modes which are rotationally symmetric with respect to the axis of the corner reflector. The light oscillated in such Laguerre-Gauss modes is totally reflected at (and cannot transmit through) the at least one side surface of the corner reflector, and emitted from the resonator through the emission window as a propagating light beam.

(b) The only difference between the operations in the laser diodes according to the first and second aspects of the present invention is that the optical paths between the corner reflector and the reflection plane in the edge-emitting LD according to the second aspect of the present invention two-dimensionally extend, while the optical paths between the corner reflector and the reflection plane in the surface-emitting LD according to the first aspect of the present invention three-dimensionally extend. Except for the above difference, light is resonated, amplified, and emitted in similar manners in the laser diodes according to the first and second aspects of the present invention. Thus, the edge-emitting LD according to the second aspect of the present invention can also emit a single-peaked beam of oscillated light which can propagate outside the laser diode, and in which high-order transverse modes are suppressed.

(c) As explained above, the laser diodes according to the present invention can emit oscillated light as a single-peaked beam of oscillated light which can propagate outside the laser diode. Therefore, when the laser diodes according to the present invention are used as a light source in optical communication, it is possible to couple the light emitted from each laser diode, to an optical fiber with high efficiency.

(d) In addition, since emission of light in high-order transverse modes is suppressed in the laser diodes according to the present invention as explained before, it is unnecessary to reduce the emission area for prevention of the emission of light in the high-order transverse modes. Since the thermal resistance can be reduced by increasing the emission area, the emission efficiency can be greatly increased in the laser diodes according to the present invention.

(e) In particular, in the surface-emitting laser diode according to the first aspect of the present invention, the upper reflection layer (which is realized by, for example, DBR layers, and constitutes a resonator) is not necessary for realizing a resonator, and may be therefore dispensed with. In the case where the surface-emitting laser diode does not contain the upper reflection layer, the active layer can be arranged near the electrode, so that heat generated by the active layer can be dissipated through the electrode. Therefore, it is possible to reduce the thermal resistance, and increase the emission efficiency.

### DESCRIPTION OF THE DRAWINGS

FIG. 1 is a schematic side view, partly in cross section, of a laser diode according to a first embodiment of the present invention.

FIG. 2 is a side view of a portion of the laser diode of FIG. 1.

FIGS. 3A and 3B are schematic side views, partly in cross section, of structures in representative stages of a process of forming a corner reflector.

FIG. 4 is a schematic side view, partly in cross section, of a laser diode according to a second embodiment of the present invention.

FIG. 5 is a side view of a portion of the laser diode of FIG. 4.

FIG. 6 is a schematic perspective view of a laser diode according to a third embodiment of the present invention.

FIG. 7 is a schematic side view, partly in cross section, of a first example of a conventional surface-emitting laser diode.

FIG. 8 is a schematic side view, partly in cross section, of a second example of a conventional surface-emitting laser diode.

FIG. 9 is a schematic perspective view of an example of a conventional edge-emitting laser diode.

FIG. 10A is a graph indicating a far-field intensity distribution of light emitted from a normal edge-emitting laser diode having a normal resonator mirror instead of the corner reflector 24.

FIG. 10B is a graph indicating a far-field intensity distribution of light emitted from the edge-emitting laser diode of FIG. 9.

### DESCRIPTION OF PREFERRED EMBODIMENTS

Embodiments of the present invention are explained in detail below with reference to drawings.

### First Embodiment

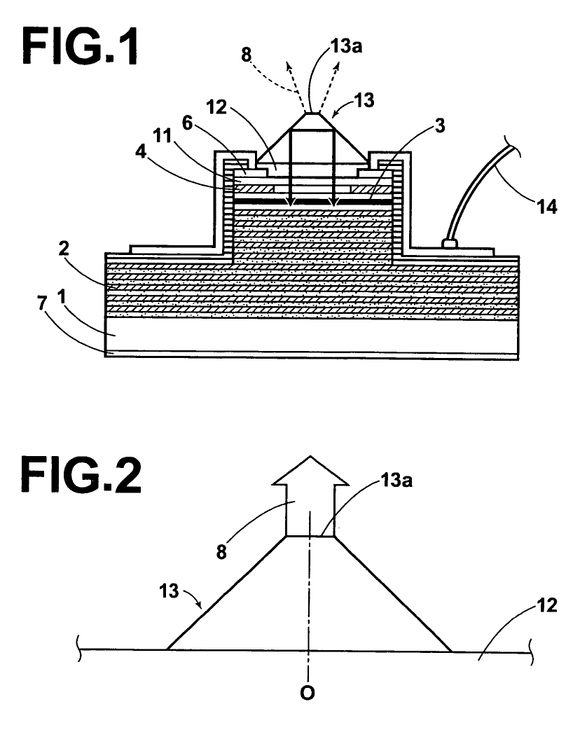

FIG. 1 is a schematic side view, partly in cross section, of a laser diode according to the first embodiment of the present invention, and FIG. 2 is a side view of a portion of the laser diode of FIG. 1. As illustrated in FIGS. 1 and 2, the laser diode according to the first embodiment is a surface-emitting LD comprising a substrate 1, layers formed on the upper side of the substrate 1, and an N electrode 7 formed on the lower side of the substrate 1. The layers formed on the upper side of the substrate 1 include lower DBR layers 2 (as a reflection layer), an active layer 3, an oxidized aperture layer 4, a semiconductor buffer layer 11, a P electrode 6, and a transparent dielectric buffer layer 12. The lower DBR layers 2 has a function of a reflection layer, the oxidized aperture layer 4 has an opening which determines an oscillation region, the semiconductor buffer layer 11 is provided for injecting current from the P electrode 6 formed on the semiconductor buffer layer 11, and the transparent dielectric buffer layer 12 is provided for protecting the semiconductor buffer layer 11. In addition, a corner reflector 13 is attached on the transparent dielectric buffer layer 12 by a process explained later. Further, a wire 14 is bonded to a contact being connected to the P electrode 6 and extending to side areas of the laser diode.

For example, in the case where the oscillation wavelength of the surface-emitting LD is 650 nm, the substrate 1 is made of GaAs, the lower DBR layers 2 are realized by alternately laminated AlAs and AlGa layers, the active layer 3 is formed of AlGaInP and InGaP, the oxidized aperture layer 4 is formed of AlAs, the semiconductor buffer layer 11 is formed of AlGaAs, the P electrode 6 is formed of Ti, Pt, and Au, and the transparent dielectric buffer layer 12 is formed of SiN.

In addition, the corner reflector 13 is formed of a material having a refractive index greater than one, for example, a transparent polymer, and has a shape obtained by cutting off a top portion (i.e., a near-vertex portion) of a cone having a vertex angle of 90 degrees by a plane approximately perpendicular to the axis O of the cone so that the top surface 13a of the corner reflector 13 becomes flat. The vertex angle is an angle which two straight lines contained in the cone and symmetric with respect to the axis of the cone make. The top surface 13a has a function of an emission window through which light oscillated in the surface-emitting LD is emitted from the laser diode as a propagating light beam 8, as explained later. The effective diameter of the top surface 13a is, for example, approximately 1 to 2 micrometers.

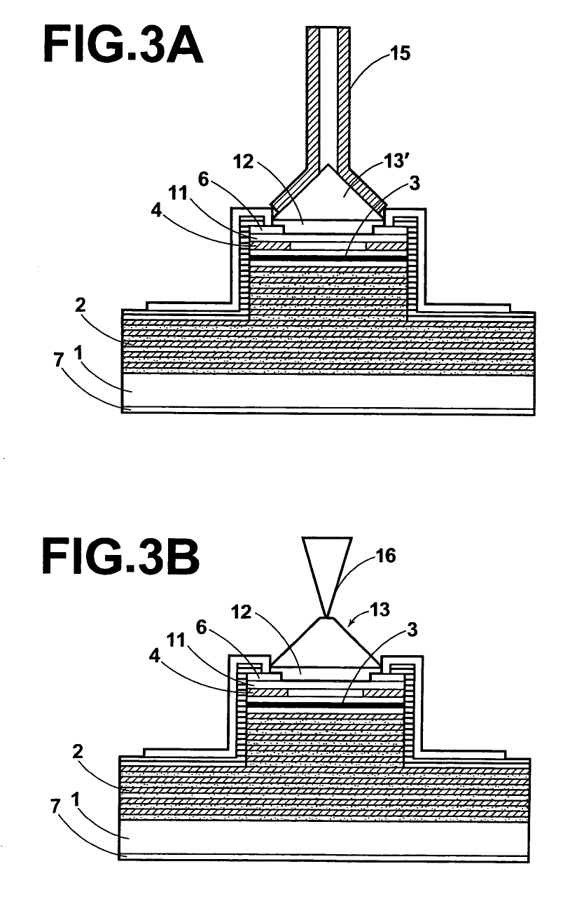

An example of a process of forming the corner reflector 13 is explained below with reference to FIGS. 3A and 3B, which are schematic side views, partly in cross section, of structures in representative stages of the process of forming the corner reflector 13.

First, the aforementioned layers up to the transparent dielectric buffer layer 12 are formed on the substrate 1. Thereafter, a guide tube 15 having an inner shape corresponding to a desired outer shape of the cone at its bottom end is placed on the transparent dielectric buffer layer 12 as illustrated in FIG. 3A, and a molten transparent material 13′ such as a molten polymer or molten glass is poured into the guide tube 15 so that the molten transparent material 13′ is deposited on the transparent dielectric buffer layer 12 with the desired outer shape of the cone. After the transparent material 13′ deposited as above solidifies, the top portion of the cone is melted by using laser light 16 as illustrated in FIG. 3B. When a desired flat shape of the top surface 13a is realized, the irradiation with the laser light 16 is stopped. Thus, the corner reflector 13 having the emission window 13a at its top is obtained.

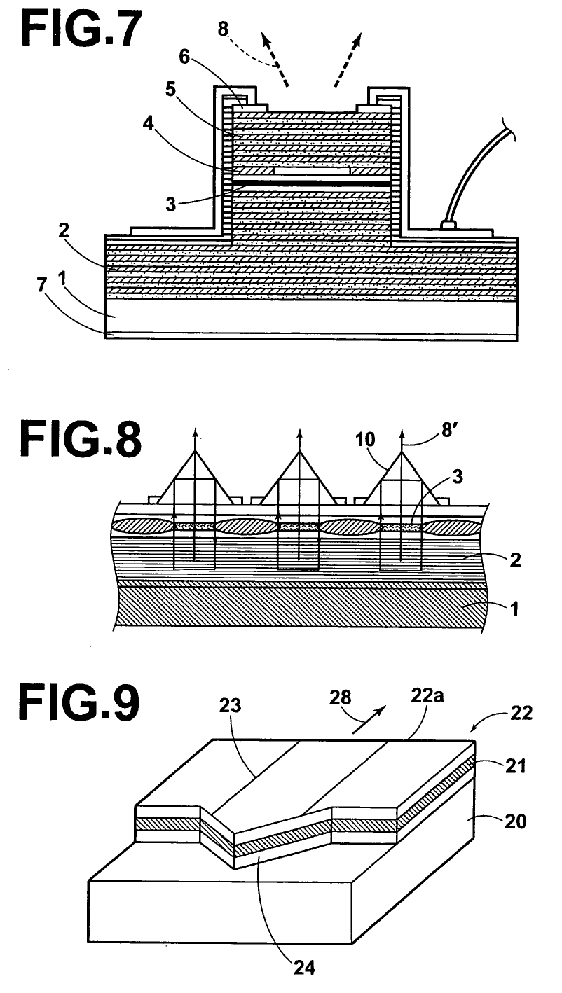

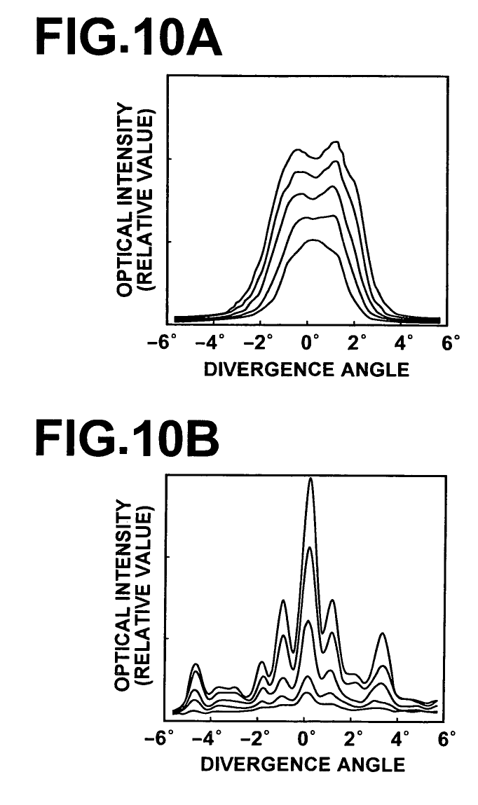

In the surface-emitting LD illustrated in FIGS. 1 and 2, laser oscillation occurs in a similar manner to the laser diode of FIG. 7. However, since the corner reflector 13 in the surface-emitting LD of FIGS. 1 and 2 has the emission window 13a, the light perpendicularly incident on the emission window 13a is not totally reflected at the emission window 13a, and the light oscillated in the laser diode is outputted (emitted) from the emission window 13a as the propagating light beam 8, which can propagate outside the laser diode. For the reason explained before, the propagating light beam 8 contains in-phase components only, and is a single-peaked beam in which high-order transverse modes are suppressed.

In addition, since the dimensions of the carrier injection opening are limited by the oxidized aperture layer 4, only the region of the active layer 3 corresponding to the opening of the oxidized aperture layer 4 is excited. That is, the opening of the oxidized aperture layer 4 almost corresponds to the opening of the oscillation region, i.e., the emission mode area.

Hereinbelow, conditions imposed on the emission window 13a for emission of the propagating light beam 8 which contains in-phase components only as mentioned above are explained.

<Condition 1>

It is necessary that the emitted light beam which can propagate outside the laser diode have a diameter equal to or greater than the beam diameter corresponding to the divergence angle of 180 degrees , and therefore the diameter of the emitted light beam is required to satisfy the inequality (1) indicated below. Thus, in order that the diameter of the emitted light beam should satisfy the inequality (1), the effective diameter D of the emission window 13a is required to satisfy the inequality (2) indicated below, where the effective diameter D is defined as the distance between the points, in a plane perpendicular to the axis of rotational symmetry of the corner reflector 13, at which the transmittance is 1/e² of the maximum transmittance in the emission window 13a.
d≧k·λ/2 (1)
D≧k·λ/2 (2)
In the inequalities (1) and (2), d is the 1/e² radius (i.e., the radius at which the intensity is 1/e² of the maximum), k is a constant determined according to the shape of the emitted beam (e.g., approximately 1.64 in the case of the Airy beam), and λ is the wavelength of the oscillated light. The inequality (2) indicates a condition for the emitted light being a propagating light beam (i.e., a light beam which can propagate) when light having a uniform intensity distribution is incident on the emission window 13a.
<Condition 2>

In order to prevent passage, through the emission window 13a, of amplitude components other than the in-phase amplitude components, the effective diameter D of the emission window 13a is required to satisfy the following condition. That is, in the resonator in the laser diode according to the present invention, only the Laguerre-Gauss modes which are rotationally symmetric with respect to the rotation axis of the corner reflector oscillate. Further, normally, not all the Laguerre-Gauss modes which are rotationally symmetric with respect to the rotation axis of the corner reflector oscillate. Specifically, Laguerre-Gauss modes of orders higher than a predetermined order n do not oscillate, or the amount of amplitude components of the oscillated light which are substantially out of phase is practically ignorable.

In the case where the emission window 13a is arranged so that only a portion of the light oscillated in the Laguerre-Gauss modes of the order n and lower orders and generated in a central emission region or a smaller region can pass through the emission window 13a, and the central emission region is a round region located in the center of the laser diode and limited by the first zero point of the intensity distribution of the light oscillated in the Laguerre-Gauss modes of the order n and lower orders, the light oscillated in the Laguerre-Gauss modes of the order n and lower orders is in phase in the central emission region or the smaller region. Therefore, it is necessary that the effective diameter D of the emission window 13a satisfy the following inequality (3), which is based on the radius of the above central emission region.
D≦(2xₘ·w²)^{1/2} (3)
In the inequality (3), xₘ is the minimum value of x which satisfies Lₙ(x)=0, Lₙ is the nth-order Laguerre polynomial, and w is the 1/e² radius of the Gaussian beam determined on the basis of the mode area.

However, it is unnecessary that the emission window 13a strictly satisfy the condition (3). Even when some out-of-phase amplitude components are contained in the light emitted from the emission window 13a, practically no problem occurs as long as the amount of the out-of-phase amplitude components is sufficiently small or ignorable. Therefore, it is sufficient that the maximum effective diameter of the emission window 13a be close to the values satisfying the inequality (3).

### Second Embodiment

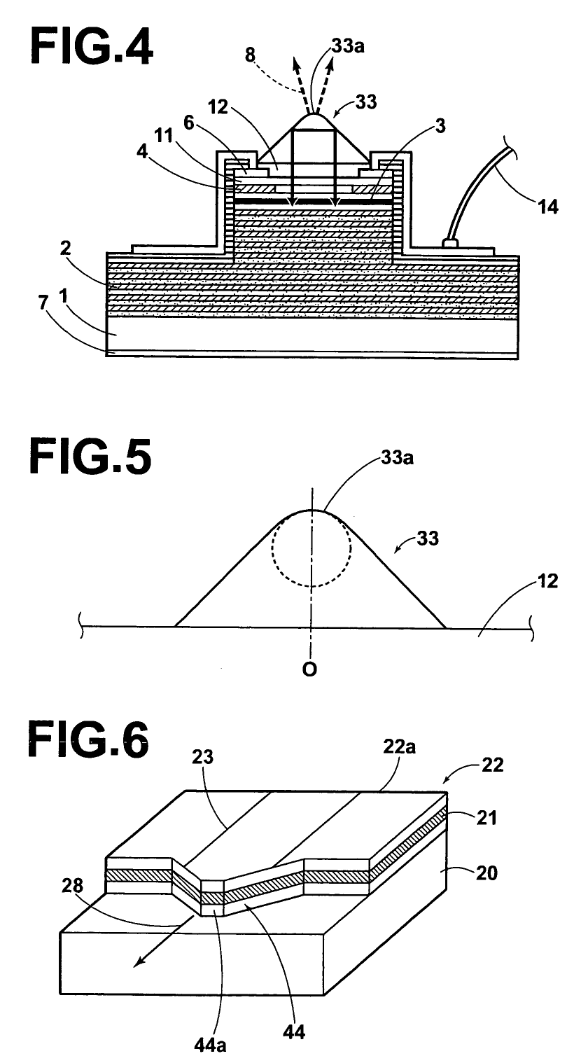

Next, a laser diode according to the second embodiment of the present invention is explained below with reference to FIGS. 4 and 5. FIG. 4 is a schematic side view, partly in cross section, of the laser diode according to the second embodiment, and FIG. 5 is a side view of a portion of the laser diode of FIG. 4.

As illustrated in FIGS. 4 and 5, the surface-emitting laser diode according to the second embodiment is basically similar to the first embodiment except that a corner reflector 33 the top portion of which is rounded to form a curved surface is arranged instead of the corner reflector 13 in the laser diode of FIGS. 1 and 2. Specifically, the corner reflector 33 has a shape obtained by rounding off the top portion of a cone having a vertex angle of 90 degrees so that the top portion of the cone forms a portion of a sphere (spherical surface) which is rotationally symmetric with respect to the axis O of the cone.

Since the corner reflector 33 in the surface-emitting LD of FIGS. 4 and 5 has the above emission window 33a, the light oscillated in the laser diode is outputted (emitted) through the emission window 33a as the propagating light beam 8, which can propagate outside the laser diode, and the propagating light beam 8 is a single-peaked beam in which high-order transverse modes are suppressed. In addition, since the emission window 33a with the spherical surface has a function of a lens, it is possible to reduce the divergence angle of the propagating light beam 8.

Further, the portion of the sphere realizing the surface of the emission window 33a may or may not be tangent to the conical surface of the corner reflector 33. Alternatively, the surface of the emission window 33a may be realized by a paraboloidal surface or another curved surface, instead of the spherical surface.

### Third Embodiment

Finally, a laser diode according to the third embodiment of the present invention is explained below with reference to FIG. 6, which is a schematic perspective view of the laser diode according to the third embodiment.

As illustrated in FIG. 6, the laser diode according to the third embodiment is an edge-emitting laser diode, and different from the conventional edge-emitting LD of FIG. 9 in the following features. That is, in the laser diode of FIG. 6, a corner reflector 44 having a shape different from the corner reflector 24 in FIG. 9 is arranged at a first end of the semiconductor layers 22, and a reflection mirror (not shown) is realized at a second end (opposite to the first end) of the semiconductor layers 22 by applying coating to the end face 22a at the second end in such a manner that the reflection mirror reflects substantially all light propagating through the stripe region 23. The other portions of the laser diode of FIG. 6 are basically similar to the corresponding portions of the laser diode of FIG. 9.

Specifically, the corner reflector 44 is formed at the first end of the semiconductor layers 22 by cutting the first end of the semiconductor layers 22 in the following manner. That is, the first end has a protrusion with a triangular cross section parallel to the semiconductor layers 22, and a top portion of the triangular protrusion is removed so that the end face at the top portion of the triangular protrusion becomes flat as illustrated in FIG. 6. The flat end face at the top portion of the triangular protrusion realizes an emission window 44a.

In the structure according to the third embodiment illustrated in FIG. 6, laser light is oscillated in a similar manner to the conventional laser diode of FIG. 9. However, since the emission window 44a is arranged in the corner reflector 44 in the laser diode of FIG. 6 as explained above, light oscillated in the laser diode and perpendicularly incident on the emission window 44a is not totally reflected by the side face of the corner reflector 44, and is outputted (emitted) through the emission window 44a as a propagating light beam 28, which can propagate outside the laser diode. At this time, the propagating light beam 28 is a single-peaked beam in which high-order transverse modes are suppressed.

Instead of forming the corner reflector 44 by cutting the end of the semiconductor layers 22, it is possible to bond, to an end face of the semiconductor layers 22, a corner reflector which is separately formed of a transparent optical material to have a predetermined shape, as in the first and second embodiments.

Alternatively, it is possible to form the corner reflectors 13 or 33 as illustrated in FIGS. 2 and 5 by cutting a semiconductor layer.

While the description above refers to particular embodiments of the present invention, it will be understood that many modifications maybe made without departing from the spirit thereof. The accompanying claims are intended to cover such modifications as would fall within the true scope and spirit of the present invention.

The presently disclosed embodiments are therefore to be considered in all respects as illustrative and not restrictive, the scope of the invention being indicated by the appended claims, rather than the foregoing description, and all changes which fall within the meaning and range of equivalency of the claims are therefore intended to be embraced therein.

For example, the surface-emitting laser diodes according to the first aspect of the present invention may also have one or any possible combination of the following additional features (i) to (vii).
(i) The emission window is realized by forming a flat surface at the portion of the corner reflector in such a manner that the flat surface is approximately perpendicular to the axis of the cone or pyramid.
(ii) The emission window is realized by forming a curved surface at the portion of the corner reflector in such a manner that the curved surface is approximately rotationally symmetric with respect to the axis of the cone or pyramid.
(iii) The reflection layer is realized by DBR layers.
(iv) The corner reflector has at least one side surface arranged in such a manner that two portions of the at least one side surface which are symmetric with respect to the axis of the cone or pyramid make an angle of 90 degrees.
(v) The emission window has an effective diameter D which satisfies the relationships,
   k·λ/2≦D≦(2xₘ·w²)^{1/2}
   where. k is a constant determined according to the shape of the light beam, λ is the wavelength of the oscillated light, xₘ is the minimum value of x which satisfies Lₙ(x)=0, Lₙ is the nth-order Laguerre polynomial, and w is the 1/e² radius of the Gaussian beam determined on the basis of the mode area.
(vi) The corner reflector can be formed of a transparent optical material which is different from the semiconductor layers, and fixed to the semiconductor layers directly or through a buffer layer.
(vii) The corner reflector can be formed by cutting one of the semiconductor layers.

In addition, the edge emitting laser diode according to the second aspect of the present invention may also have one or any combination of the above additional features.

Additional Matters

In addition, all of the contents of the Japanese patent application No. 2004-266695 are incorporated into this specification by reference.

What is claimed is:

1. A surface-emitting laser diode comprising:
a substrate;
a reflection layer formed on said substrate;
an active layer formed above said reflection layer;
a corner reflector which has a shape approximately corresponding to a portion of one of a cone and a pyramid having a vertex, and is arranged above said active layer with the vertex up in such a manner that the corner reflector and said reflection layer realize a resonator; and
an emission window which is formed at a portion of the corner reflector containing said vertex, and has such dimensions that substantially only components of oscillated light in a fundamental transverse mode are emitted as a light beam which can propagate outside the surface-emitting laser diode.

2. A surface-emitting laser diode according to claim 1, wherein said emission window is realized by forming a flat surface at said portion of the corner reflector in such a manner that the flat surface is approximately perpendicular to an axis of said one of the cone and the pyramid.

3. A surface-emitting laser diode according to claim 1, wherein said emission window is realized by forming a curved surface at said portion of the corner reflector in such a manner that the curved surface is approximately rotationally symmetric with respect to an axis of said one of the cone and the pyramid.

4. A surface-emitting laser diode according to claim 1, wherein said reflection layer is realized by DBR layers.

5. A surface-emitting laser diode according to claim 2, wherein said reflection layer is realized by DBR layers.

6. A surface-emitting laser diode according to claim 3, wherein said reflection layer is realized by DBR layers.

7. A surface-emitting laser diode according to claim 1, wherein said corner reflector has at least one side surface arranged in such a manner that two portions of the at least one side surface which are symmetric with respect to an axis of said one of the cone and the pyramid make an angle of 90 degrees.

8. A surface-emitting laser diode according to claim 2, wherein said corner reflector has at least one side surface arranged in such a manner that two portions of the at least one side surface which are symmetric with respect to an axis of said one of the cone and the pyramid make an angle of 90 degrees.

9. A surface-emitting laser diode according to claim 3, wherein said corner reflector has at least one side surface arranged in such a manner that two portions of the at least one side surface which are symmetric with respect to an axis of said one of the cone and the pyramid make an angle of 90 degrees.

10. A surface-emitting laser diode according to claim 4, wherein said corner reflector has at least one side surface arranged in such a manner that two portions of the at least one side surface which are symmetric with respect to an axis of said one of the cone and the pyramid make an angle of 90 degrees.

11. A surface-emitting laser diode according to claim 1, wherein said emission window has an effective diameter D which satisfies the relationships,
k·λ/2≦D≦(2xₘ·w²)^{1/2},
where k is a constant determined according to a shape which said light beam has, λ is a wavelength which said oscillated light has, xₘ is the minimum value of x which satisfies Lₙ(x)=0, Lₙ is the nth-order Laguerre polynomial, and w is a 1/e² radius of a Gaussian beam determined on the basis of a mode area.

12. A surface-emitting laser diode according to claim 2, wherein said emission window has an effective diameter D which satisfies the relationships,
k·λ/2≦D≦(2xₘ·w²)^{1/2},
where k is a constant determined according to a shape which said light beam has, λ is a wavelength which said oscillated light has, xₘ is the minimum value of x which satisfies Lₙ(x)=0, Lₙ is the nth-order Laguerre polynomial, and w is a 1/e² radius of a Gaussian beam determined on the basis of a mode area.

13. A surface-emitting laser diode according to claim 3, wherein said emission window has an effective diameter D which satisfies the relationships,
k·λ/2≦D≦(2xₘ·w²)^{1/2},
where k is a constant determined according to a shape which said light beam has, λ is a wavelength which said oscillated light has, xₘ is the minimum value of x which satisfies Lₙ(x)=0, Lₙ is the nth-order Laguerre polynomial, and w is a 1/e² radius of a Gaussian beam determined on the basis of a mode area.

14. A surface-emitting laser diode according to claim 4, wherein said emission window has an effective diameter D which satisfies the relationships,
k·λ/2≦D≦(2xₘ·w²)^{1/2},
where k is a constant determined according to a shape which said light beam has, λ is a wavelength which said oscillated light has, xₘ is the minimum value of x which satisfies Lₙ(x)=0, Lₙ is the nth-order Laguerre polynomial, and w is a 1/e² radius of a Gaussian beam determined on the basis of a mode area.

15. A surface-emitting laser diode according to claim 5, wherein said emission window has an effective diameter D which satisfies the relationships,
k·λ/2≦D≦(2xₘ·w²)^{1/2},
where k is a constant determined according to a shape which said light beam has, λ is a wavelength which said oscillated light has, xₘ is the minimum value of x which satisfies Lₙ(x)=0, Lₙ is the nth-order Laguerre polynomial, and w is a 1/e² radius of a Gaussian beam determined on the basis of a mode area.

16. A surface-emitting laser diode according to claim 6, wherein said emission window has an effective diameter D which satisfies the relationships,
k·λ/2≦D≦(2xₘ·w²)^{1/2},
where k is a constant determined according to a shape which said light beam has, λ is a wavelength which said oscillated light has, xₘ is the minimum value of x which satisfies Lₙ(x)=0, Lₙ is the nth-order Laguerre polynomial, and w is a 1/e² radius of a Gaussian beam determined on the basis of a mode area.

17. A surface-emitting laser diode according to claim 7, wherein said emission window has an effective diameter D which satisfies the relationships,
k·λ/2≦D≦(2xₘ·w²)^{1/2},
where k is a constant determined according to a shape which said light beam has, λ is a wavelength which said oscillated light has, xₘ is the minimum value of x which satisfies Lₙ(x)=0, Lₙ is the nth-order Laguerre polynomial, and w is a 1/e² radius of a Gaussian beam determined on the basis of a mode area.

18. An edge-emitting laser diode comprising:
a substrate;
semiconductor layers which includes an active layer, and is formed on said substrate;
an optical waveguide which allows propagation of light so that the light passes through said active layer;
a reflection face which is formed at a first end of said semiconductor layers, and reflects light being able to propagate through said optical waveguide;
a corner reflector which is formed at a second end of said semiconductor layers so as to have a protrusion with an approximately triangular cross section parallel to the semiconductor layers in such a manner that an outermost portion of the protrusion corresponds to a vertex of the approximately triangular cross section, and the corner reflector and said reflection face realize a resonator; and
an emission window which is formed at said outermost portion, and has such dimensions that substantially only components of oscillated light in a fundamental transverse mode are emitted as a light beam which can propagate outside the edge-emitting laser diode.

19. An edge-emitting laser diode according to claim 18, wherein said emission window has an effective diameter D which satisfies the relationships,
k·λ/2≦D≦(2xₘ·w²)^{1/2},
where k is a constant determined according to a shape which said light beam has, is a wavelength which said oscillated light has, xₘ is the minimum value of x which satisfies Lₙ(x)=0, Lₙ is the nth-order Laguerre polynomial, and w is a 1/e² radius of a Gaussian beam determined on the basis of a mode area.
